(19) United States
(12) Patent Application Publication
(10) Pub. No.: US 2007/0145426 A1
(43) Pub. Date: Jun. 28, 2007

(54) IMAGE SENSOR

(76) Inventor: Sang Sik Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,781

(22) Filed: Dec. 27, 2006

(30) Foreign Application Priority Data
Dec. 28, 2005 (KR) 10-2005-0131370

(51) Int. Cl. H01L 27/148

(52) U.S. Cl. 257/234

(57) ABSTRACT

Embodiments relate to an image sensor. In embodiments, the image sensor may include a semiconductor substrate formed with a plurality of photodiodes, an interlayer dielectric layer formed on the semiconductor substrate, a color filter layer formed on the interlayer dielectric layer, a planar layer formed on the color filter layer, and a micro-lens formed on the planar layer. A hole having a predetermined pattern is formed on a top surface of the interlayer dielectric layer. The hole having the prescribed pattern may be formed in the interlayer dielectric layer. Accordingly, an adhesive force between the interlayer dielectric layer and the color filter layer formed on the interlayer dielectric layer may be improved. This may enable fabrication of an image sensor having high-sensitivity without causing a defective pixel.

The present application claims priority under 35 U.S.C. 119 and 35 U.S.C. 365 to Korean Patent Application No. 10-2005-0131370 (filed on Dec. 28, 2005), which is hereby incorporated by reference in its entirety.

### BACKGROUND

An image sensor may be a semiconductor device that may convert optical images into electric signals, and may be mainly classified into a charge coupled device (CCD) image sensor and a CMOS image sensor.

Such an image sensor may include a photodiode that may detect light. The image sensor may further include a logic circuit that may convert detected light into electric signals. The detected light may thereby be represented as data. As an amount of light received in the photodiode increases, the photo sensitivity of the image sensor may improve.

Photo sensitivity may be improved by various methods. For example, a fill factor, which may be a ratio of a photodiode area to the whole area of the image sensor, may be increased. Alternatively, photo-gathering technology may be used to change a path of light incident onto an area other than the photodiode area such that the light may be gathered in the photodiode.

A micro-lens is an example of the photo-gathering technology. For example, a convex micro-lens may be formed on a top surface of a photodiode. The micro-lens may be formed using a material having superior light transmittance. The micro-lens may refract a path of incident light in such a manner that a greater amount of light may be transmitted into the photo-diode area. Hence, light parallel to an optical axis of the micro-lens may be refracted by the micro-lens, and light may be focused at a specific position on the optical axis.

A related art image sensor may include various components, such as a photodiode, an interlayer dielectric layer, a color filter, a micro-lens, and so on.

An interlayer dielectric layer may be formed on a semiconductor substrate formed with a plurality of photodiodes. RGB color filter layers may be formed on the interlayer dielectric layer and may correspond (i.e. be aligned) with the photodiodes, respectively.

A planar layer may be formed on the color filter layers and may planarize an irregular surface that may occur on the color filter layers. In addition, micro-lenses may be formed on the planar layer to correspond with the photodiodes and the color filter layers, respectively.

The photodiode may detect light and may convert the light into an electric signal. The interlayer dielectric layer may insulate metal interconnections from each other. The color filter may exhibit the three primary colors of red, green, and blue (R, G, B). The micro-lens may guide the light onto the photodiode.

FIG. 1 illustrates a related art image sensor.

Referring to FIG. 1, interlayer dielectric layer 20 may be formed on semiconductor substrate 10. Semiconductor substrate 10 may have a plurality of photodiodes 40 formed thereon. In addition, R, G and B color filters 30 may be formed on the interlayer dielectric layer 20 and may correspond with locations of the plurality of photodiodes 40, respectively.

Planar layer 25 may be formed on color filter layers 30 and may planarize an irregular surface of color filter layers 30. In addition, micro-lenses 50 may be formed on planar layer 25, and may correspond to locations of photodiodes 40 and color filter layers 30, respectively.

However, if color filter layers 30 are formed directly on interlayer dielectric layer 20, a peeling phenomenon may occur. The peeling phenomenon may occur because materials that may form color filter layers 30 may have poor adhesive properties, which may cause defective pixels.

### SUMMARY

Embodiments relate to an image sensor. Embodiments relate to an image sensor that may be capable of improving sensitivity without causing defected pixels by forming a hole having a prescribed pattern on a top surface of an interlayer dielectric layer.

Embodiments relate to an image sensor that may not cause defected pixels and may improve an adhesive property of a color filter layer by forming a hole having a prescribed pattern on an interlayer dielectric layer. Embodiments relate to a method of manufacturing such an image sensor.

In embodiments, an image sensor may include a semiconductor substrate formed with a plurality of photodiodes, an interlayer dielectric layer formed on the semiconductor substrate, a color filter layer formed on the interlayer dielectric layer, a planar layer formed on the color filter layer, and a micro-lens formed on the planar layer, wherein a hole having a prescribed pattern may be formed on a top surface of the interlayer dielectric layer.

In embodiments, a interlayer dielectric layer may include photoresist, and the hole having the prescribed pattern formed on the top surface of the interlayer dielectric layer may have a circular shape or a polygonal shape.

In embodiments, a method of manufacturing an image sensor may include preparing a semiconductor substrate formed with a plurality of photodiodes, forming an interlayer dielectric layer on the semiconductor substrate, forming a hole having a prescribed pattern on a top surface of the interlayer dielectric layer, forming a color filter layer on the interlayer dielectric layer including the hole having the prescribed pattern, forming a planar layer on the color filter layer, and forming a micro-lens on the planar layer.

### BRIEF DESCRIPTION OF THE DRAWINGS

FIG. 1 is an example diagram illustrating a related art image sensor;

FIG. 2 is an example diagram illustrating an image sensor according to embodiments;

FIGS. 3A and 3B are sectional views taken along line A-A′ of FIG. 2;

FIG. 4 is an example diagram illustrating an image sensor according to embodiments; and

FIGS. 5A to 5E are example diagrams illustrating an image sensor and a procedure for manufacturing an image sensor according to embodiments.

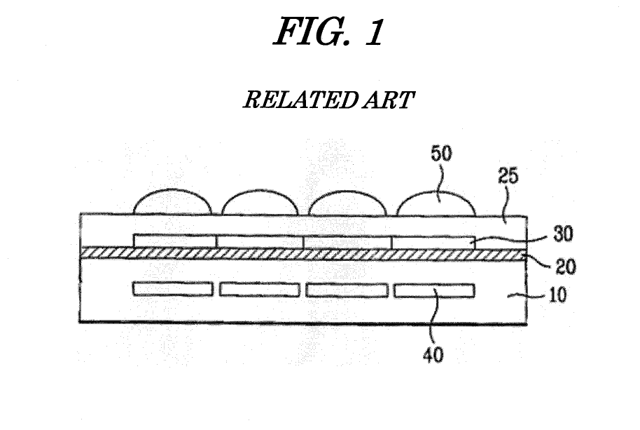

### DETAILED DESCRIPTION OF EMBODIMENTS

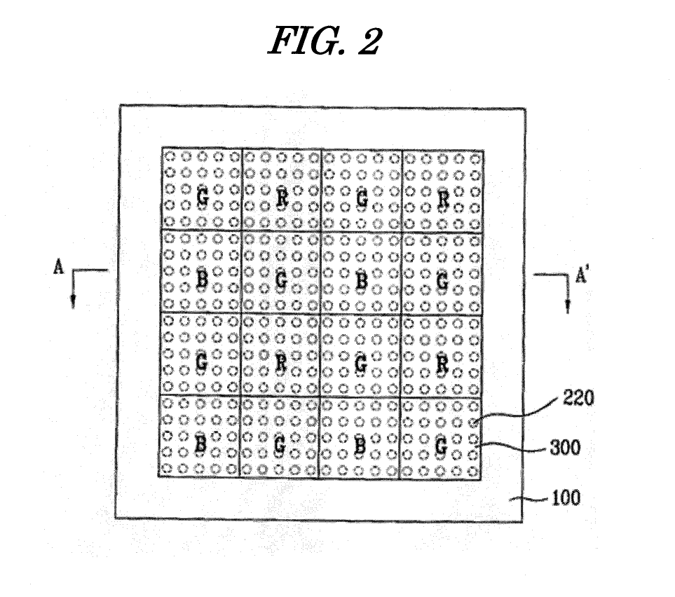

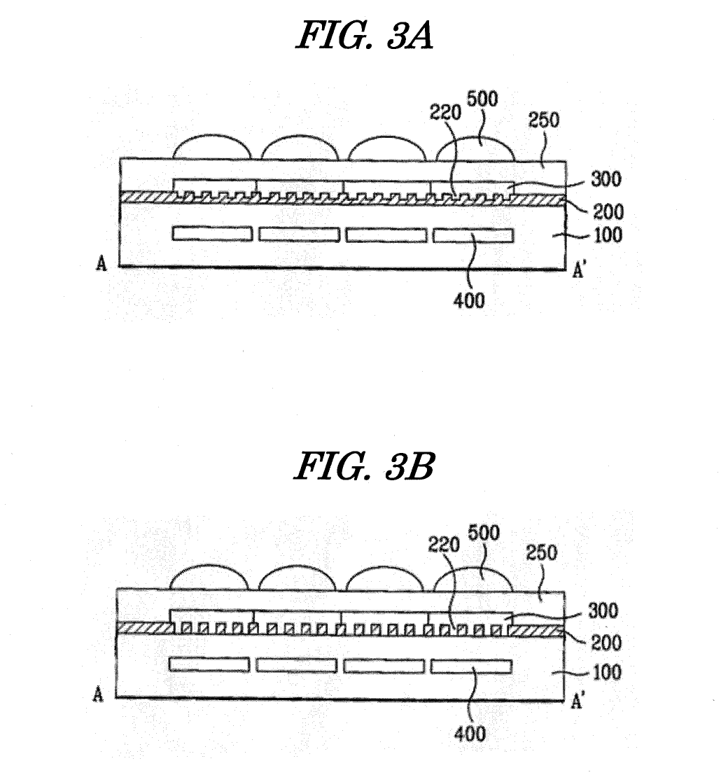

FIG. 2 is an example diagram illustrating an image sensor according to embodiments, and FIGS. 3A and 3B are sectional views taken along line A-A′ of FIG. 2.

Referring to FIG. 2, an interlayer dielectric layer (not shown) may include hole 220. The interlayer dielectric layer may have a prescribed pattern and may be formed on semiconductor substrate 100. Color filter layer 300 may be formed on the interlayer dielectric layer.

Color filter layer 300 may include R, B and G pixels, which may be alternatively aligned in the form of a matrix pattern.

Referring to FIG. 3A, semiconductor substrate 100 may include a plurality of photodiodes 400, and interlayer dielectric layer 200, including hole 220 having the prescribed pattern, may be formed on semiconductor substrate 100.

Interlayer dielectric layer 200 may be a photoresist or may include a photoresist, according to embodiments. Embodiments may not be limited thereto, but various materials may be used for interlayer dielectric layer 200. In embodiments, materials that may have superior photosensitive properties corresponding to that of photoresist may be used, as may materials that may easily form the pattern.

In embodiments, hole 220 formed in interlayer dielectric layer 200 may be a shallow hole as shown in FIG. 3A. In embodiments, however, as shown in FIG. 3B, hole 220 may extend through interlayer dielectric layer 200.

Referring to FIG. 3B, if hole 220 extends through interlayer dielectric layer 200, an adhesive property of color filter layer 300 may be improved. Light transmittance may also be improved because the interlayer dielectric layer 220 may be removed at an area where hole 220 may be formed.

As the light transmittance of the image sensor improves, the image sensor may be able to photograph an image in a relatively dark place and may also improve a color reproduction property.

Hole 220 may be formed with various sizes. In embodiments, sizes may range from about 10 nm to a size of a pixel.

In addition, a number of the holes 220 may be variously established. The adhesive force of color filter layer 300 may be significantly improved if a plurality of holes are formed with micro-sizes, instead of forming a single hole having a large size.

Color filter layers 300 may be formed on interlayer dielectric layer 200 including hole 220 having the prescribed pattern that may correspond (i.e. be aligned) with locations of photodiodes 400 provided in semiconductor substrate 100, respectively.

Planar layer 250 may be provided on color filter layer 300. Planar layer 250 may planarize a top surface of color filter layer 300, and may protect color filter layer 300. Micro-lenses 500 may be formed on planar layer 250.

Planar layer 250 may include organic materials that may have superior transparency in a visual spectrum to effectively protect color filter layer 300, to easily form the micro-lens 500 on planar layer 250, and to adjust a focal length.

Micro-lens 500 may include photoresist, or an insulating material having superior insulating characteristics while allowing light to pass therethrough.

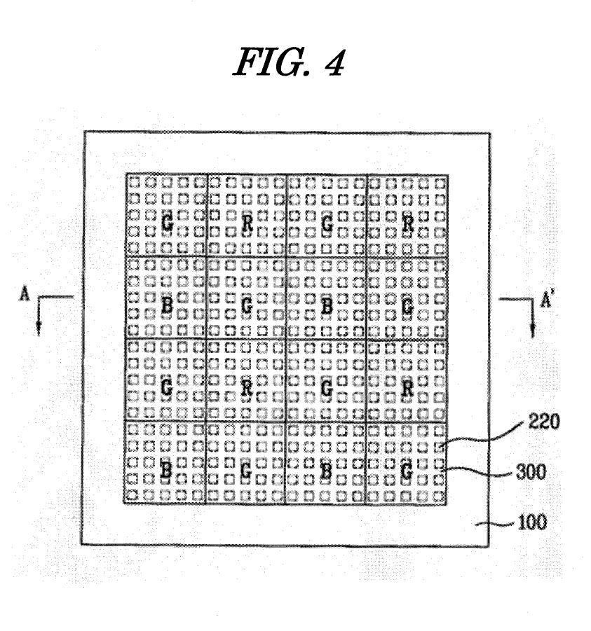

FIG. 4 is an example diagram illustrating an image sensor according to embodiments.

As illustrated in FIG. 4, a structure of the image sensor according to embodiments may be substantially identical to that of the image sensor illustrated in FIGS. 2, 3A, and 3B, except for the shape of hole 220 formed in the interlayer dielectric layer (not shown).

Referring to FIG. 4, hole 220, which may be formed in the interlayer dielectric layer (not shown), may have a rectangular shape instead of a circular shape. In addition, although it is not illustrated in figures, the interlayer dielectric layer may have a polygonal shape.

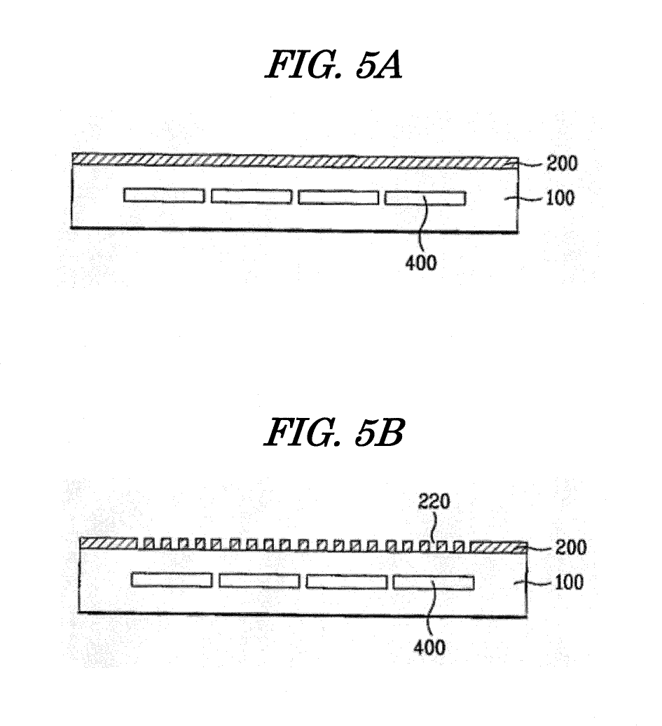

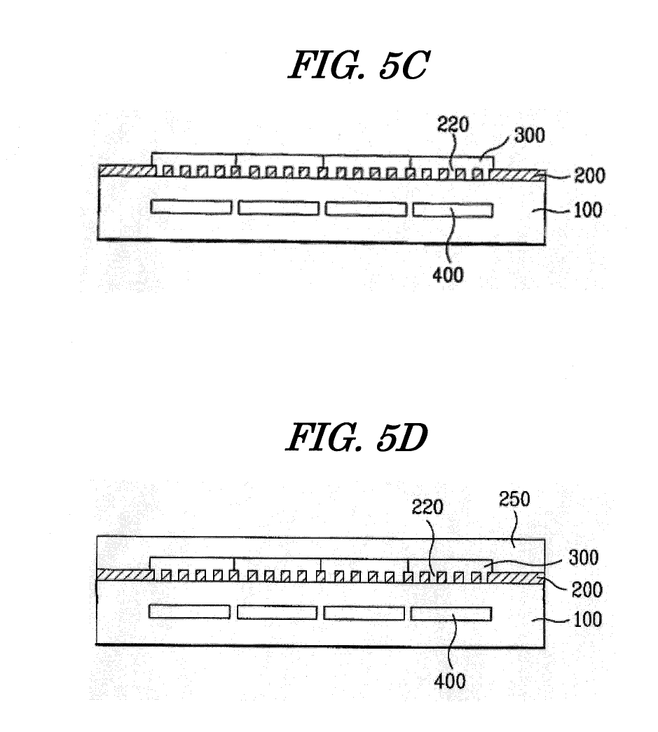

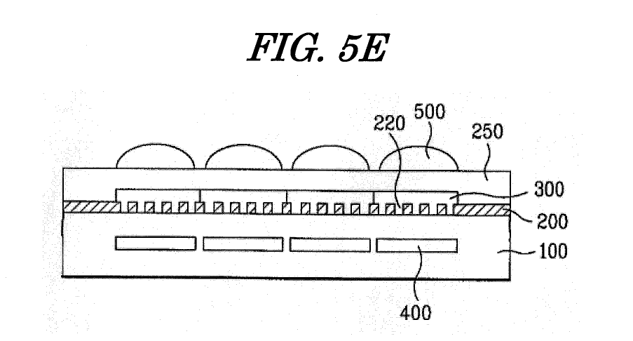

FIGS. 5A to 5E are example diagrams illustrating a procedure for manufacturing an image sensor according to embodiments.

Referring to FIG. 5A, semiconductor substrate 100 may be formed with a plurality of photodiodes 400 thereon. Interlayer dielectric layer 200 may be formed on semiconductor substrate 100.

Referring to FIG. 5B, hole 220, which may have a prescribed pattern, may be formed on a top surface of interlayer dielectric layer 200. In embodiments, hole 220 may include a perforation hole that extends through interlayer dielectric layer 200, as shown in FIG. 5B. However, it may also be possible to form hole 220 as a shallow hole, according to embodiments.

Referring to FIG. 5C, color filter layer 300 may be formed on interlayer dielectric layer 200 including hole 220 having the prescribed pattern.

Color filter layers 300 may be aligned corresponding to positions of photodiodes 400 provided in semiconductor substrate 100, respectively.

Referring to FIG. 5D, planar layer 250 may be formed on color filter layer 300.

Referring to FIG. 5E, micro-lenses 500 may be formed on planar layer 250, thereby obtaining the image sensor.

According to embodiments, the hole having the prescribed pattern may be formed in the interlayer dielectric layer. An adhesive force between the interlayer dielectric layer and the color filter layer formed on the interlayer dielectric layer may thereby be improved. This may prevent a peeling phenomenon.

Since a peeling phenomenon may be prevented, the probability of the defective pixels may be lowered. Hence, a yield rate of the image sensor may be improved.

In addition, since the hole may be formed in the interlayer dielectric layer, absorption of light incident from the exterior may be reduced, and light efficiency may be improved. Accordingly, it may be possible to fabricate an image sensor having high-sensitivity.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. An device, comprising:
a semiconductor substrate formed with at least one photodiode;
an interlayer dielectric layer formed over the semiconductor substrate;
a color filter layer formed over the interlayer dielectric layer;
a planar layer formed over the color filter layer; and
a micro-lens formed over the planar layer,
wherein at least one hole having a prescribed pattern is formed on a top surface of the interlayer dielectric layer.

2. The device of claim 1, wherein the interlayer dielectric layer comprises photoresist.

3. The device of claim 1, wherein the at least one hole comprises at least one of a circular shape and a polygonal shape.

4. The device of claim 1, wherein the at least one hole comprise a plurality of holes.

5. The device of claim 1, wherein the prescribed pattern of the at least one hole corresponds to locations of the at least one photodiode, such that the at least one hole is aligned with at least one photodiode.

6. The device of claim 5, wherein the at least one hole extends all the way through the interlayer dielectric layer.

7. The device of claim 1, wherein a size of the at least one hole is at least 10 nm.

8. A method, comprising:
preparing a semiconductor substrate formed to include a plurality of photodiodes;
forming an interlayer dielectric layer over the semiconductor substrate;
forming at least one hole having a prescribed pattern over a top surface of the interlayer dielectric layer; and
forming a color filter layer over the interlayer dielectric layer including the hole having the prescribed pattern.

9. The method of claim 8, further comprising:
forming a planar layer over the color filter layer; and
forming a micro-lens on the planar layer.

10. The method of claim 8, wherein the at least one hole comprises at least one of a circular shape and a polygonal shape.

11. The method of claim 8, wherein the at least one hole is formed to a prescribed depth within the interlayer dielectric layer.

12. The method of claim 11, wherein the at least one hole is formed to extend all the way through the interlayer dielectric layer.

13. The method of claim 11, wherein the at least one hole comprise a plurality of holes, and wherein a location of the plurality of holes corresponds to locations of the plurality of photodiodes, such that at least one hole is aligned with each photodiode.

14. A device, comprising:
an interlayer dielectric layer formed over a semiconductor substrate, the interlayer dielectric layer having at least one hole formed thereon; and
a color filter formed over the interlayer dielectric layer.

15. The device of claim 14, wherein the interlayer dielectric layer comprises a plurality of holes formed thereon.

16. The device of claim 15, wherein each of the plurality of holes comprises at least one of a circular shaped hole and a polygonal shaped hole.

17. The device of claim 16, wherein a size of each of the plurality of holes is approximately 10 nm.

18. The device of claim 14, wherein the at least one hole extends through the interlayer dielectric layer.

19. The device of claim 14, further comprising:
a plurality of photodiodes on the semiconductor substrate;
a planar layer over the interlayer dielectric layer and the color filter layer; and
a plurality of micro-lenses over the planar layer.

20. The device of claim 19, wherein the at least one hole comprises a plurality of holes formed to have a prescribed pattern such that each hole is aligned with a corresponding photodiode, and wherein a size of each of the plurality of holes ranges from approximately 10 nm to a size of a pixel.
